(19) United States
(12) Patent Application Publication
(10) Pub. No.: US 2023/0411575 A1
(43) Pub. Date: Dec. 21, 2023

(54) DISPLAY DEVICE AND METHOD FOR MANUFACTURING SAME

(71) Applicant: LG ELECTRONICS INC., Seoul (KR)

(72) Inventors: Kyoungtae WI, Seoul (KR); Byungjoon RHEE, Seoul (KR); Hwanjoon CHOI, Seoul (KR)

(73) Assignee: LG ELECTRONICS INC., Seoul (KR)

(21) Appl. No.: 18/036,358

(22) PCT Filed: Nov. 10, 2020
(86) PCT No.: PCT/KR2020/015684

§ 371 Date: May 10, 2023

(51) Int. Cl. H01L 33/62; H01L 25/075; H01L 33/38

(52) U.S. Cl. CPC H01L 33/62; H01L 25/0753; H01L 2933/0016; H01L 2933/0066; H01L 33/38

(57) ABSTRACT

Disclosed are a display device using a semiconductor light emitting element, and a method for manufacturing same. In order to achieve the above objective, the display device according to an embodiment of the present disclosure may comprise: a wiring substrate; wiring electrodes at least partially placed on the wiring substrate; light emitting elements each electrically connected to a wiring electrode corresponding thereto, among the wiring electrodes; adhesive patterns having an adhesive property for bonding the wiring electrodes and the light emitting elements and a transfer property required for transferring the light emitting elements to the wiring electrodes, wherein each of the adhesive patterns may be formed for at least one combined pair formed by a wiring electrode and a light emitting element electrically connected to each other, among the wiring electrodes and the light emitting elements, and the adhesive patterns are formed to be spaced apart from each other.

### TECHNICAL FIELD

The present disclosure relates to a display device and a method of manufacturing the same.

### BACKGROUND ART

Recently, in a field of a display technology, display devices having excellent property such as thinness, flexibility, and the like have been developed. On the other hand, currently commercialized major displays are represented by an LCD (liquid crystal display) and an OLED (organic light emitting diode).

On the other hand, an LED (light emitting diode), which is a well-known semiconductor light-emitting device that converts electric current into light, has been used as a light source for a display image of an electronic device including an information and communication device along with a GaP:N-based green LED, starting with commercialization of a red LED using a GaAsP compound semiconductor in 1962. Accordingly, a method for solving the above-described problems by implementing a display using the semiconductor light-emitting device may be proposed.

The semiconductor light emitting device is transferred onto a substrate in various ways. However, the number of times of transfer is increased to electrically couple the semiconductor light emitting device and a wiring electrode, thereby causing problems such as a decrease in production yield and an increase in production cost.

### DISCLOSURE

### Technical Problem

An object of the present disclosure is to provide a display device capable of improving production yield and lowering production cost by reducing the number of times of transfer for electrically connecting a light emitting device and a wiring electrode, and a method of manufacturing the same.

### Technical Solution

To achieve the object, a display device in accordance with an embodiment of the present disclosure includes a wiring substrate; wiring electrodes, at least a part of which is positioned on the wiring substrate; light emitting devices connected electrically to related wiring electrodes, respectively, among the wiring electrodes, and adhesive patterns having adhesive property for bonding the wiring electrodes and the light emitting devices and transfer property required to transfer the light emitting devices to the wiring electrode. The adhesive patterns may be formed respectively for at least one bonding pair including a wiring electrode and a light emitting device connected electrically to each other among the wiring electrodes and the light emitting devices and be spaced apart from each other.

The adhesive patterns may be respectively related to the same number of bonding pairs among the bonding pairs.

First sub-patterns among the adhesive patterns may be respectively related to a first number of bonding pairs among the bonding pairs, and second sub-patterns among the adhesive patterns may be respectively related to a second number of bonding pairs among the bonding pairs.

Each of the adhesive patterns may be formed to integrally surround bonding pairs included in the adhesive pattern.

Each of the adhesive patterns may be formed of a non-conductive paste (NCP) phase-changeable to a semi-solid state.

The NCP may include an ultraviolet (UV) B-stage composition and a thermosetting composition.

Content of the UV B-stage composition in the NCP may be 20% to 50%.

The NCP may have a viscosity of 10,000 to 100,000 centipoise (cps).

The NCP may include at least one of acrylate or epoxy acrylate.

An adhesive pattern related to bonding pairs constituting one pixel among the at least one bonding pair may have a constant curvature.

The wiring electrodes may include first wiring electrodes and second wiring electrodes electrically connected to related device electrodes, respectively, among first device electrodes and second device electrodes of the light emitting devices; and all of the first wiring electrodes and the second wiring electrodes may be formed on one surface of the wiring substrate.

The wiring electrodes may include first wiring electrodes and second wiring electrodes electrically connected to related device electrodes, respectively, among first device electrodes and second device electrodes of the light emitting devices, and the first wiring electrodes may be formed on one surface of the wiring substrate and the second wiring electrodes may be formed facing the first wiring electrodes with the light emitting devices interposed between the first wiring electrodes and the second wiring electrodes.

Each of the light emitting devices may include a micro-light emitting device (LED).

To achieve the object, a method of manufacturing a display device in accordance with an embodiment of the present disclosure includes growing light emitting devices on a growth substrate; forming at least a part of wiring electrodes on a wiring substrate; patterning adhesive patterns spaced apart from each other and having adhesive property for bonding the wiring electrodes and the light emitting devices and transfer property required to transfer the light emitting devices to the wiring electrode; and transferring the light emitting devices to the wiring electrodes so that bonding pairs each including a related wiring electrode and a related light emitting device among the wiring electrodes and the light emitting devices are bonded through the adhesive patterns.

The patterning the adhesive patterns may include performing patterning by dispensing, pattern-printing, or inkjet-printing an adhesive material on the wiring substrate.

The patterning the adhesive patterns includes at least one of: patterning the adhesive patterns to be related respectively to the same number of bonding pairs among the bonding pairs; or patterning first sub-patterns among the adhesive patterns to be related respectively to a first number of bonding pairs among the bonding pairs, and patterning second sub-patterns among the adhesive patterns to be related respectively to a second number of bonding pairs among the bonding pairs.

The method may further include phase-changing the adhesive patterns to a semi-solid state at the same time as the transferring the light emitting devices to the wiring electrodes or immediately after the transferring the light emitting devices to the wiring electrodes.

The phase-changing the adhesive patterns to the semi-solid state may include an ultraviolet (UV) B-stage.

The method may further include performing laser lift-off (LLO) on the growth substrate after the phase-changing the adhesive patterns to the semi-solid state.

The method may further include repeating the transferring the light emitting devices to the wiring electrodes to complete transfer for each pixel; and simultaneously thermally compressing and bonding light emitting devices of each pixel after completing the transferring each pixel.

### Advantageous Effects

A display device and a method of manufacturing the same according to an embodiment of the present invention may simplify a process, reduce cost, and secure mass productivity by directly transferring a light emitting device from a wafer (a growth substrate) onto a wiring substrate using an adhesive pattern having both adhesive property and transfer property in electrically connecting an electrode of the light emitting device and a wiring electrode.

The display device and the method of manufacturing the same according to an embodiment of the present disclosure eliminate a process of transferring a light emitting device from a wafer onto a temporary substrate, thereby preventing positional movement of the light emitting device that may occur in the transfer process and improving yield.

The display device and the method of manufacturing the same according to an embodiment of the present disclosure may alleviate impact applied to a light emitting device when the light emitting device is separated from a wafer because an adhesive pattern sufficiently surrounds the light emitting device.

The display device and the method of manufacturing the same according to an embodiment of the present disclosure may sufficiently secure a flow space of an adhesive material by separately providing an adhesive pattern for one or multiple of light emitting devices from an adhesive pattern for other light emitting devices and thus uniformly maintain property even for a large-area process. For example, gap filling property and consistency (planarization) of bonding thickness may be satisfied.

The display device and the method of manufacturing the same according to an embodiment of the present disclosure individually transfer light emitting devices exhibiting different colors and then simultaneously perform bonding processes, thereby preventing a lighting failure problem caused by interference and collision, which is affected by a light emitting device bonded first and a bonding process performed later, upon performing a separate bonding process for a light emitting device of each color.

### BRIEF DESCRIPTION OF DRAWINGS

FIG. 1 is a conceptual diagram illustrating an embodiment of a display device using a semiconductor light emitting device according to the present disclosure;

FIG. 2 is a partially enlarged diagram showing a part A shown in FIG. 1, and FIGS. 3A and 3B are cross-sectional diagrams taken along the cutting lines B-B and C-C in FIG. 2;

FIG. 4 is a conceptual diagram illustrating the flip-chip type semiconductor light emitting device of FIG. 3:

FIGS. 5A to 5C are conceptual diagrams illustrating various examples of color implementation with respect to a flip-chip type semiconductor light emitting device:

FIG. 6 shows cross-sectional views of a method of fabricating a display device using a semiconductor light emitting device according to the present disclosure;

FIG. 7 is a cross-sectional diagram taken along a cutting line D-D shown in FIG. 6;

FIG. 8 is a conceptual diagram showing a vertical type semiconductor light emitting device shown in FIG. 7;

FIGS. 9 and 10 are diagrams each illustrating a display device according to an embodiment of the present disclosure:

FIG. 11 is a flowchart illustrating a manufacturing method of a display device according to an embodiment of the present disclosure:

FIG. 12 is a diagram illustrating an embodiment of the manufacturing method of FIG. 11;

FIGS. 13 to 15 are diagrams illustrating adhesive patterns according to an embodiment of the present disclosure;

FIG. 16 is a diagram illustrating a manufacturing method of a display device according to a comparative example compared with the present disclosure;

FIG. 17 is a diagram illustrating a manufacturing method of a display device according to an embodiment of the present disclosure; and

FIG. 18A is a diagram conceptually illustrating the shape of an adhesive pattern after completion of a bonding operation according to an embodiment of the present disclosure, and FIG. 18B is a diagram conceptually illustrating the shape of an adhesive pattern after completion of a bonding operation according to a comparative example compared with the present disclosure.

### BEST MODE

Reference will now be made in detail to embodiments of the present disclosure, examples of which are illustrated in the accompanying drawings. Wherever possible, the same reference numbers will be used throughout the drawings to refer to the same or like parts, and redundant description thereof will be omitted. As used herein, the suffixes “module” and “unit” are added or used interchangeably to facilitate preparation of this specification and are not intended to suggest distinct meanings or functions. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification.

In addition, when an element such as a layer, region or module is described as being “on” another element, it is to be understood that the element may be directly on the other element or there may be an intermediate element between them.

The display device described herein is a concept including a mobile phone, a smartphone, a laptop, a digital broadcasting terminal, a personal digital assistant (PDA), a portable multimedia player (PMP), a navigation system, a slate PC, a tablet, an Ultrabook, a digital TV, a desktop computer, and the like. However, it will be readily apparent to those skilled in the art that the configuration according to the embodiments described herein is applicable even to a new product that will be developed later as a display device.

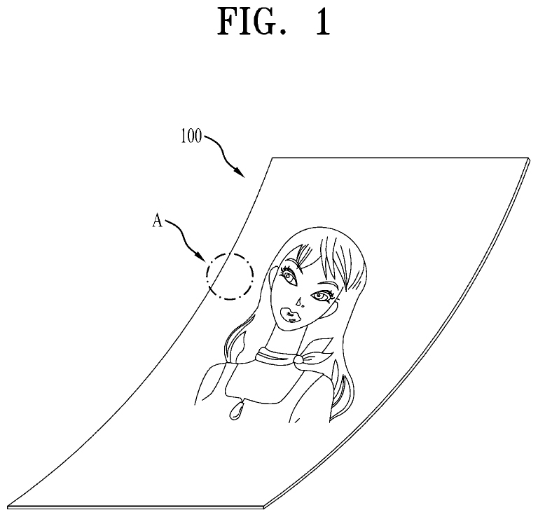

FIG. 1 is a conceptual view illustrating an embodiment of a display device using a semiconductor light emitting device according to the present disclosure.

According to the drawings, information processed by a controller (not shown) of a display device 100 may be displayed using a flexible display.

The flexible display may include, for example, a display that can be warped, bent, twisted, folded, or rolled by external force. For example, the flexible display may be, for example, a display manufactured on a thin and flexible substrate that can be warped, bent, folded, or rolled like paper while maintaining the display property of a conventional flat panel display.

When the flexible display remains in an unbent state (e.g., a state having an infinite radius of curvature) (hereinafter referred to as a first state), the display area of the flexible display forms a flat surface. When the display in the first sate is changed to a bent state (e.g., a state having a finite radius of curvature) (hereinafter referred to as a second state) by external force, the display area may be a curved surface. As shown in FIG. 1, the information displayed in the second state may be visual information output on a curved surface. Such visual information may be implemented by independently controlling the light emission of sub-pixels arranged in a matrix form. The unit pixel may mean, for example, a minimum unit for implementing one color.

The unit pixel of the flexible display may be implemented by a semiconductor light emitting device. In the present disclosure, a light emitting diode (LED) is exemplified as a type of the semiconductor light emitting device configured to convert electric current into light. The LED may be formed in a small size, and may thus serve as a unit pixel even in the second state.

Hereinafter, a flexible display implemented using the LED will be described in more detail with reference to the drawings.

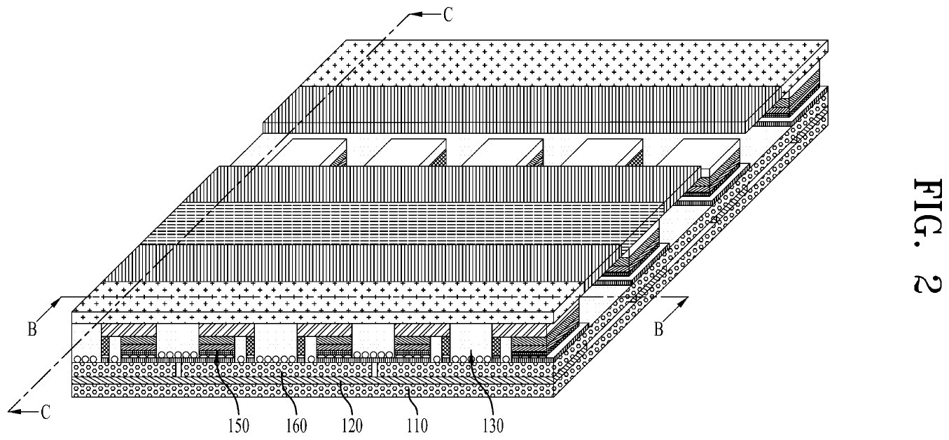

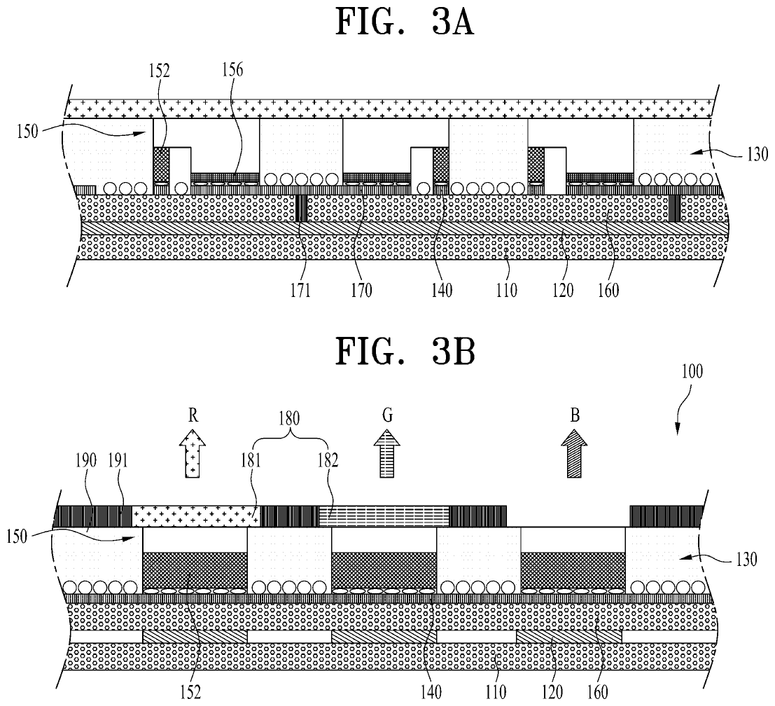

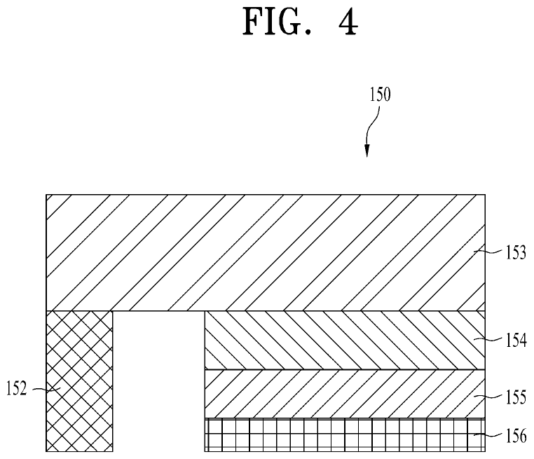

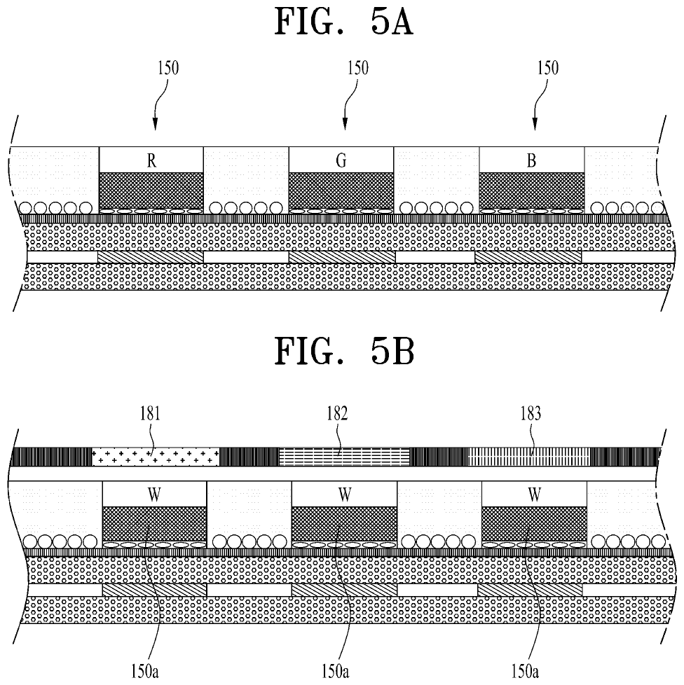

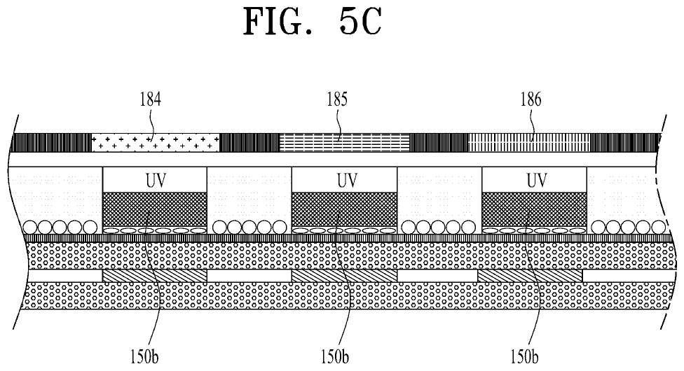

FIG. 2 is a partially enlarged view showing part A of FIG. 1, FIGS. 3A and 3B are cross-sectional views taken along lines B-B and C-C in FIG. 2, FIG. 4 is a conceptual view illustrating the flip-chip type semiconductor light emitting device of FIG. 3, and FIGS. 5A to 5C are conceptual views illustrating various examples of implementation of colors in relation to a flip-chip type semiconductor light emitting device.

As shown in FIGS. 2, 3A and 3B, the display device 100 using a passive matrix (PM) type semiconductor light emitting device is exemplified as the display device 100 using a semiconductor light emitting device. However, the examples described below are also applicable to an active matrix (AM) type semiconductor light emitting device.

The display device 100 may include a substrate 110, a first electrode 120, a conductive adhesive layer 130, a second electrode 140, and at least one semiconductor light emitting device 150.

The substrate 110 may be a flexible substrate. For example, to implement a flexible display device, the substrate 110 may include glass or polyimide (PI). Any insulative and flexible material such as polyethylene naphthalate (PEN) or polyethylene terephthalate (PET) may be employed. In addition, the substrate 110 may be formed of either a transparent material or an opaque material.

The substrate 110 may be a wiring substrate on which the first electrode 120 is disposed. Thus, the first electrode 120 may be positioned on the substrate 110.

According to the drawings, an insulating layer 160 may be disposed on the substrate 110 on which the first electrode 120 is positioned, and an auxiliary electrode 170 may be positioned on the insulating layer 160. In this case, a stack in which the insulating layer 160 is laminated on the substrate 110 may be a single wiring substrate. More specifically, the insulating layer 160 may be formed of an insulative and flexible material such as PI, PET, or PEN, and may be integrated with the substrate 110 to form a single substrate.

The auxiliary electrode 170, which is an electrode that electrically connects the first electrode 120 and the semiconductor light emitting device 150, is positioned on the insulating layer 160, and is disposed to correspond to the position of the first electrode 120. For example, the auxiliary electrode 170 may have a dot shape and may be electrically connected to the first electrode 120 by an electrode hole 171 formed through the insulating layer 160. The electrode hole 171 may be formed by filling a via hole with a conductive material.

According to the drawings, a conductive adhesive layer 130 may be formed on one surface of the insulating layer 160, but embodiments of the present disclosure are not limited thereto. For example, a layer performing a specific function may be formed between the insulating layer 160 and the conductive adhesive layer 130, or the conductive adhesive layer 130 may be disposed on the substrate 110 without the insulating layer 160. In a structure in which the conductive adhesive layer 130 is disposed on the substrate 110, the conductive adhesive layer 130 may serve as an insulating layer.

The conductive adhesive layer 130 may be a layer having adhesiveness and conductivity. For this purpose, a material having conductivity and a material having adhesiveness may be mixed in the conductive adhesive layer 130. In addition, the conductive adhesive layer 130 may have ductility, thereby providing making the display device flexible.

As an example, the conductive adhesive layer 130 may be an anisotropic conductive film (ACF), an anisotropic conductive paste, a solution containing conductive particles, or the like. The conductive adhesive layer 130 may be configured as a layer that allows electrical interconnection in the direction of the Z-axis extending through the thickness, but is electrically insulative in the horizontal X-Y direction. Accordingly, the conductive adhesive layer 130 may be referred to as a Z-axis conductive layer (hereinafter, referred to simply as a “conductive adhesive layer”).

The ACF is a film in which an anisotropic conductive medium is mixed with an insulating base member. When the ACF is subjected to heat and pressure, only a specific portion thereof becomes conductive by the anisotropic conductive medium. Hereinafter, it will be described that heat and pressure are applied to the ACF. However, another method may be used to make the ACF partially conductive. The other method may be, for example, application of only one of the heat and pressure or UV curing.

In addition, the anisotropic conductive medium may be, for example, conductive balls or conductive particles. For example, the ACF may be a film in which conductive balls are mixed with an insulating base member. Thus, when heat and pressure are applied to the ACF, only a specific portion of the ACF is allowed to be conductive by the conductive balls. The ACF may contain a plurality of particles formed by coating the core of a conductive material with an insulating film made of a polymer material. In this case, as the insulating film is destroyed in a portion to which heat and pressure are applied, the portion is made to be conductive by the core. At this time, the cores may be deformed to form layers that contact each other in the thickness direction of the film. As a more specific example, heat and pressure are applied to the whole ACF, and an electrical connection in the Z-axis direction is partially formed by the height difference of a counterpart adhered by the ACF.

As another example, the ACF may contain a plurality of particles formed by coating an insulating core with a conductive material. In this case, as the conductive material is deformed (pressed) in a portion to which heat and pressure are applied, the portion is made to be conductive in the thickness direction of the film. As another example, the conductive material may be disposed through the insulating base member in the Z-axis direction to provide conductivity in the thickness direction of the film. In this case, the conductive material may have a pointed end.

According to the drawings, the ACF may be a fixed array ACF in which conductive balls are inserted into one surface of the insulating base member. More specifically, the insulating base member may be formed of an adhesive material, and the conductive balls may be intensively disposed on the bottom portion of the insulating base member. Thus, when the base member is subjected to heat and pressure, it may be deformed together with the conductive balls, exhibiting conductivity in the vertical direction.

However, the present disclosure is not necessarily limited thereto, and the ACF may be formed by randomly mixing conductive balls in the insulating base member, or may include a plurality of layers with conductive balls arranged on one of the layers (as a double-ACF).

The anisotropic conductive paste may be a combination of a paste and conductive balls, and may be a paste in which conductive balls are mixed with an insulating and adhesive base material. Also, the solution containing conductive particles may be a solution containing any conductive particles or nanoparticles.

Referring back to the drawings, the second electrode 140 is positioned on the insulating layer 160 and spaced apart from the auxiliary electrode 170. That is, the conductive adhesive layer 130 is disposed on the insulating layer 160 having the auxiliary electrode 170 and the second electrode 140 positioned thereon.

After the conductive adhesive layer 130 is formed with the auxiliary electrode 170 and the second electrode 140 positioned on the insulating layer 160, the semiconductor light emitting device 150 is connected thereto in a flip-chip form by applying heat and pressure. Thereby, the semiconductor light emitting device 150 is electrically connected to the first electrode 120 and the second electrode 140.

Referring to FIG. 4, the semiconductor light emitting device may be a flip chip-type light emitting device.

For example, the semiconductor light emitting device may include a p-type electrode 156, a p-type semiconductor layer 155 on which the p-type electrode 156 is formed, an active layer 154 formed on the p-type semiconductor layer 155, an n-type semiconductor layer 153 formed on the active layer 154, and an n-type electrode 152 disposed on the n-type semiconductor layer 153 and horizontally spaced apart from the p-type electrode 156. In this case, the p-type electrode 156 may be electrically connected to the auxiliary electrode 170, which is shown in FIG. 3, by the conductive adhesive layer 130, and the n-type electrode 152 may be electrically connected to the second electrode 140.

Referring back to FIGS. 2, 3A and 3B, the auxiliary electrode 170 may be elongated in one direction. Thus, one auxiliary electrode may be electrically connected to the plurality of semiconductor light emitting devices 150. For example, p-type electrodes of semiconductor light emitting devices on left and right sides of an auxiliary electrode may be electrically connected to one auxiliary electrode.

More specifically, the semiconductor light emitting device 150 may be press-fitted into the conductive adhesive layer 130 by heat and pressure. Thereby, only the portions of the semiconductor light emitting device 150 between the p-type electrode 156 and the auxiliary electrode 170 and between the n-type electrode 152 and the second electrode 140 may exhibit conductivity, and the other portions of the semiconductor light emitting device 150 do not exhibit conductivity as they are not press-fitted. In this way, the conductive adhesive layer 130 interconnects and electrically connects the semiconductor light emitting device 150 and the auxiliary electrode 170 and interconnects and electrically connects the semiconductor light emitting device 150 and the second electrode 140.

The plurality of semiconductor light emitting devices 150 may constitute a light emitting device array, and a phosphor conversion layer 180 may be formed on the light emitting device array.

The light emitting device array may include a plurality of semiconductor light emitting devices having different luminance values. Each semiconductor light emitting device 150 may constitute a unit pixel and may be electrically connected to the first electrode 120. For example, a plurality of first electrodes 120 may be provided, and the semiconductor light emitting devices may be arranged in, for example, several columns. The semiconductor light emitting devices in each column may be electrically connected to any one of the plurality of first electrodes.

In addition, since the semiconductor light emitting devices are connected in a flip-chip form, semiconductor light emitting devices grown on a transparent dielectric substrate may be used. The semiconductor light emitting devices may be, for example, nitride semiconductor light emitting devices. Since the semiconductor light emitting device 150 has excellent luminance, it may constitute an individual unit pixel even when it has a small size.

According to the drawings, a partition wall 190 may be formed between the semiconductor light emitting devices 150. In this case, the partition wall 190 may serve to separate individual unit pixels from each other, and may be integrated with the conductive adhesive layer 130. For example, by inserting the semiconductor light emitting device 150 into the ACF, the base member of the ACF may form the partition wall.

In addition, when the base member of the ACF is black, the partition wall 190 may have reflectance and increase contrast even without a separate black insulator.

As another example, a reflective partition wall may be separately provided as the partition wall 190. In this case, the partition wall 190 may include a black or white insulator depending on the purpose of the display device. When a partition wall including a white insulator is used, reflectivity may be increased. When a partition wall including a black insulator is used, it may have reflectance and increase contrast.

The phosphor conversion layer 180 may be positioned on the outer surface of the semiconductor light emitting device 150. For example, the semiconductor light emitting device 150 may be a blue semiconductor light emitting device that emits blue (B) light, and the phosphor conversion layer 180 may function to convert the blue (B) light into a color of a unit pixel. The phosphor conversion layer 180 may be a red phosphor 181 or a green phosphor 182 constituting an individual pixel.

That is, the red phosphor 181 capable of converting blue light into red (R) light may be laminated on a blue semiconductor light emitting device at a position of a unit pixel of red color, and the green phosphor 182 capable of converting blue light into green (G) light may be laminated on the blue semiconductor light emitting device at a position of a unit pixel of green color. Only the blue semiconductor light emitting device may be used alone in the portion constituting the unit pixel of blue color. In this case, unit pixels of red (R), green (G), and blue (B) may constitute one pixel. More specifically, a phosphor of one color may be laminated along each line of the first electrode 120. Accordingly, one line on the first electrode 120 may be an electrode for controlling one color. That is, red (R), green (G), and blue (B) may be sequentially disposed along the second electrode 140, thereby implementing a unit pixel.

However, embodiments of the present disclosure are not limited thereto. Unit pixels of red (R), green (G), and blue (B) may be implemented by combining the semiconductor light emitting device 150 and the quantum dot (QD) rather than using the phosphor.

Also, a black matrix 191 may be disposed between the phosphor conversion layers to improve contrast. That is, the black matrix 191 may improve contrast of light and darkness.

However, embodiments of the present disclosure are not limited thereto, and anther structure may be applied to implement blue, red, and green colors.

Referring to FIG. 5A, each semiconductor light emitting device may be implemented as a high-power light emitting device emitting light of various colors including blue by using gallium nitride (GaN) as a main material and adding indium (In) and/or aluminum (Al).

In this case, each semiconductor light emitting device may be a red, green, or blue semiconductor light emitting device to form a unit pixel (sub-pixel). For example, red, green, and blue semiconductor light emitting devices R, G, and B may be alternately disposed, and unit pixels of red, green, and blue may constitute one pixel by the red, green and blue semiconductor light emitting devices. Thereby, a full-color display may be implemented.

Referring to FIG. 5B, the semiconductor light emitting device 150a may include a white light emitting device W having a yellow phosphor conversion layer, which is provided for each device. In this case, in order to form a unit pixel, a red phosphor conversion layer 181, a green phosphor conversion layer 182, and a blue phosphor conversion layer 183 may be disposed on the white light emitting device W. In addition, a unit pixel may be formed using a color filter repeating red, green, and blue on the white light emitting device W.

Referring to FIG. 5C, a red phosphor conversion layer 181, a green phosphor conversion layer 185, and a blue phosphor conversion layer 183 may be provided on an ultraviolet light emitting device. Not only visible light but also ultraviolet (UV) light may be used in the entire region of the semiconductor light emitting device. In an embodiment, UV may be used as an excitation source of the upper phosphor in the semiconductor light emitting device.

Referring back to this example, the semiconductor light emitting device is positioned on the conductive adhesive layer to constitute a unit pixel in the display device. Since the semiconductor light emitting device has excellent luminance, individual unit pixels may be configured despite even when the semiconductor light emitting device has a small size. Regarding the size of such an individual semiconductor light emitting device, the length of each side of the device may be, for example, 80 μm or less, and the device may have a rectangular or square shape. When the semiconductor light emitting device has a rectangular shape, the size thereof may be less than or equal to 20 μm×80 μm.

In addition, even when a square semiconductor light emitting device having a side length of 10 μm is used as a unit pixel, sufficient brightness to form a display device may be obtained. Therefore, for example, in case of a rectangular pixel having a unit pixel size of 600 μm×300 μm (i.e., one side by the other side), a distance of a semiconductor light emitting device becomes sufficiently long relatively. Thus, in this case, it is able to implement a flexible display device having high image quality over HD image quality.

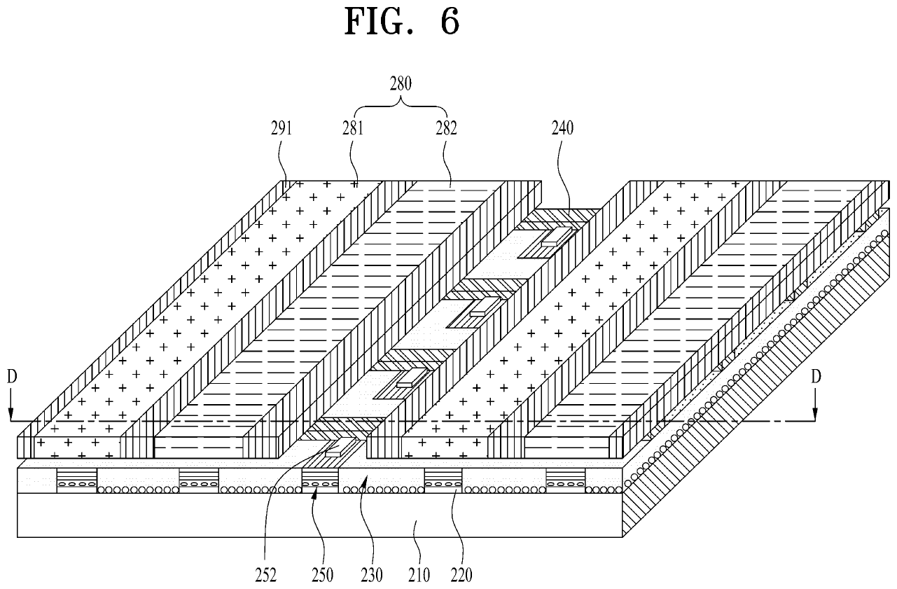

The above-described fabricating method or structure of the display device using the semiconductor light emitting device may be modified into various forms. For example, the above-described display device may employ a vertical semiconductor light emitting device. Hereinafter, the vertical structure is described with reference to FIG. 6 to FIG. 9.

Furthermore, a modification or embodiment described in the following may use the same or similar reference numbers for the same or similar configurations of the former example and the former description may apply thereto.

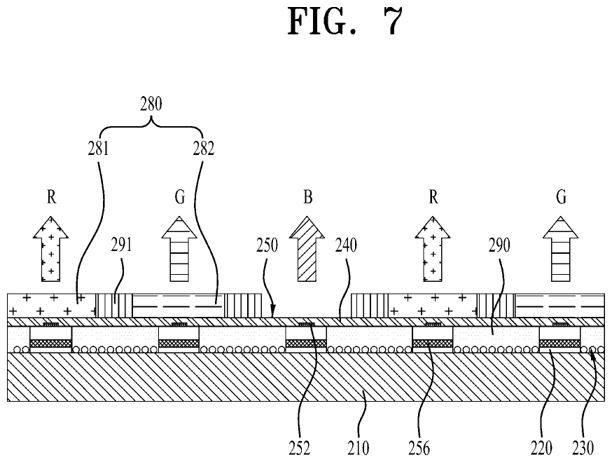

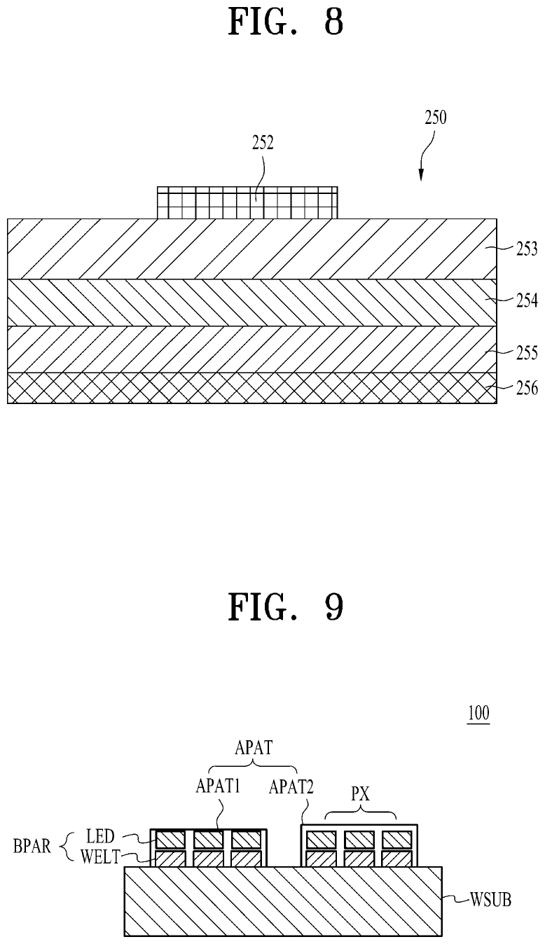

FIG. 6 is a perspective diagram of a display device using a semiconductor light emitting device according to another embodiment of the present disclosure, FIG. 7 is a cross-sectional diagram taken along a cutting line D-D shown in FIG. 6, and FIG. 8 is a conceptual diagram showing a vertical type semiconductor light emitting device shown in FIG. 7.

Referring to the present drawings, a display device may employ a vertical semiconductor light emitting device of a Passive Matrix (PM) type.

The display device includes a substrate 210, a first electrode 220, a conductive adhesive layer 230, a second electrode 240 and at least one semiconductor light emitting device 250.

The substrate 210 is a wiring substrate on which the first electrode 220 is disposed and may contain polyimide (PI) to implement a flexible display device. Besides, the substrate 210 may use any substance that is insulating and flexible.

The first electrode 210 is located on the substrate 210 and may be formed as a bar type electrode that is long in one direction. The first electrode 220 may be configured to play a role as a data electrode.

The conductive adhesive layer 230 is formed on the substrate 210 where the first electrode 220 is located. Like a display device to which a light emitting device of a flip chip type is applied, the conductive adhesive layer 230 may include one of an Anisotropic Conductive Film (ACF), an anisotropic conductive paste, a conductive particle contained solution and the like. Yet, in the present embodiment, a case of implementing the conductive adhesive layer 230 with the anisotropic conductive film is exemplified.

After the conductive adhesive layer has been placed in the state that the first electrode 220 is located on the substrate 210, if the semiconductor light emitting device 250 is connected by applying heat and pressure thereto, the semiconductor light emitting device 250 is electrically connected to the first electrode 220. In doing so, the semiconductor light emitting device 250 is preferably disposed to be located on the first electrode 220.

If heat and pressure is applied to an anisotropic conductive film, as described above, since the anisotropic conductive film has conductivity partially in a thickness direction, the electrical connection is established. Therefore, the anisotropic conductive film is partitioned into a conductive portion and a non-conductive portion.

Furthermore, since the anisotropic conductive film contains an adhesive component, the conductive adhesive layer 230 implements mechanical coupling between the semiconductor light emitting device 250 and the first electrode 220 as well as mechanical connection.

Thus, the semiconductor light emitting device 250 is located on the conductive adhesive layer 230, via which an individual pixel is configured in the display device. As the semiconductor light emitting device 250 has excellent luminance, an individual unit pixel may be configured in small size as well. Regarding a size of the individual semiconductor light emitting device 250, a length of one side may be equal to or smaller than 80 μm for example and the individual semiconductor light emitting device 250 may include a rectangular or square device. For example, the rectangular device may have a size equal to or smaller than 20 μm×80 μm.

The semiconductor light emitting device 250 may have a vertical structure.

Among the vertical type semiconductor light emitting devices, a plurality of second electrodes 240 respectively and electrically connected to the vertical type semiconductor light emitting devices 250 are located in a manner of being disposed in a direction crossing with a length direction of the first electrode 220.

Referring to FIG. 8, the vertical type semiconductor light emitting device 250 includes a p-type electrode 256, a p-type semiconductor layer 255 formed on the p-type electrode 256, an active layer 254 formed on the p-type semiconductor layer 255, an n-type semiconductor layer 253 formed on the active layer 254, and an n-type electrode 252 formed on then-type semiconductor layer 253. In this case, the p-type electrode 256 located on a bottom side may be electrically connected to the first electrode 220 by the conductive adhesive layer 230, and the n-type electrode 252 located on a top side may be electrically connected to a second electrode 240 described later. Since such a vertical type semiconductor light emitting device 250 can dispose the electrodes at top and bottom, it is considerably advantageous in reducing a chip size.

Referring to FIG. 7 again, a phosphor layer 280 may formed on one side of the semiconductor light emitting device 250. For example, the semiconductor light emitting device 250 may include a blue semiconductor light emitting device 251 emitting blue (B) light, and a phosphor layer 280 for converting the blue (B) light into a color of a unit pixel may be provided. In this regard, the phosphor layer 280 may include a red phosphor 281 and a green phosphor 282 configuring an individual pixel.

Namely, at a location of configuring a red unit pixel, the red phosphor 281 capable of converting blue light into red (R) light may be stacked on a blue semiconductor light emitting device. At a location of configuring a green unit pixel, the green phosphor 282 capable of converting blue light into green (G) light may be stacked on the blue semiconductor light emitting device. Moreover, the blue semiconductor light emitting device may be singly usable for a portion that configures a blue unit pixel. In this case, the unit pixels of red (R), green (G) and blue (B) may configure a single pixel.

Yet, the present disclosure is non-limited by the above description. In a display device to which a light emitting device of a flip chip type is applied, as described above, a different structure for implementing blue, red and green may be applicable.

Regarding the present embodiment again, the second electrode 240 is located between the semiconductor light emitting devices 250 and connected to the semiconductor light emitting devices electrically. For example, the semiconductor light emitting devices 250 are disposed in a plurality of columns, and the second electrode 240 may be located between the columns of the semiconductor light emitting devices 250.

Since a distance between the semiconductor light emitting devices 250 configuring the individual pixel is sufficiently long, the second electrode 240 may be located between the semiconductor light emitting devices 250.

The second electrode 240 may be formed as an electrode of a bar type that is long in one direction and disposed in a direction vertical to the first electrode.

In addition, the second electrode 240 and the semiconductor light emitting device 250 may be electrically connected to each other by a connecting electrode protruding from the second electrode 240. Particularly, the connecting electrode may include a n-type electrode of the semiconductor light emitting device 250. For example, the n-type electrode is formed as an ohmic electrode for ohmic contact, and the second electrode covers at least one portion of the ohmic electrode by printing or deposition. Thus, the second electrode 240 and the n-type electrode of the semiconductor light emitting device 250 may be electrically connected to each other.

According to the drawings, the second electrode 240 may be located on the conductive adhesive layer 230. In some cases, a transparent insulating layer (not shown) containing silicon oxide (SiOx) and the like may be formed on the substrate 210 having the semiconductor light emitting device 250 formed thereon. If the second electrode 240 is placed after the transparent insulating layer has been formed, the second electrode 240 is located on the transparent insulating layer. Alternatively, the second electrode 240 may be formed in a manner of being spaced apart from the conductive adhesive layer 230 or the transparent insulating layer.

If a transparent electrode of Indium Tin Oxide (ITO) or the like is sued to place the second electrode 240 on the semiconductor light emitting device 250, there is a problem that ITO substance has poor adhesiveness to an n-type semiconductor layer. Therefore, according to the present disclosure, as the second electrode 240 is placed between the semiconductor light emitting devices 250, it is advantageous in that a transparent electrode of ITO is not used. Thus, light extraction efficiency can be improved using a conductive substance having good adhesiveness to an n-type semiconductor layer as a horizontal electrode without restriction on transparent substance selection.

According to the drawings, a partition 290 may be located between the semiconductor light emitting devices 250. Namely, in order to isolate the semiconductor light emitting device 250 configuring the individual pixel, the partition 290 may be disposed between the vertical type semiconductor light emitting devices 250. In this case, the partition 290 may play a role in separating the individual unit pixels from each other and be formed with the conductive adhesive layer 230 as an integral part. For example, by inserting the semiconductor light emitting device 250 in an anisotropic conductive film, a base member of the anisotropic conductive film may form the partition.

In addition, if the base member of the anisotropic conductive film is black, the partition 290 may have reflective property as well as a contrast ratio may be increased, without a separate block insulator.

For another example, a reflective partition may be separately provided as the partition 190. The partition 290 may include a black or white insulator depending on the purpose of the display device.

In case that the second electrode 240 is located right onto the conductive adhesive layer 230 between the semiconductor light emitting devices 250, the partition 290 may be located between the vertical type semiconductor light emitting device 250 and the second electrode 240 each. Therefore, an individual unit pixel may be configured using the semiconductor light emitting device 250. Since a distance between the semiconductor light emitting devices 250 is sufficiently long, the second electrode 240 can be placed between the semiconductor light emitting devices 250. And, it may bring an effect of implementing a flexible display device having HD image quality.

In addition, according to the drawings, a black matrix 291 may be disposed between the respective phosphors for the contrast ratio improvement. Namely, the black matrix 291 may improve the contrast between light and shade.

As described above, the semiconductor light emitting device 250 is located on the conductive adhesive layer 230 to constitute an individual pixel in the display device through such a configuration. Since the semiconductor light emitting device 250 has excellent luminance, the semiconductor light emitting device 250 even with a small size may constitute an individual unit pixel. Accordingly, full-color display in which unit pixels of red (R), green (G), and blue (B) constitute a single pixel may be implemented by the semiconductor light emitting device.

An ACF is utilized in the display device described above. The ACF (hereinafter, referred to as an anisotropic conductive layer) is made of a mixture of conductive balls (hereinafter referred to as conductive particles) and an insulating material. When a substrate on which a semiconductor light emitting device is formed is thermally compressed on a wiring substrate coated with the anisotropic conductive layer, a wiring electrode and the semiconductor light emitting device are electrically connected by the conductive particles.

During thermal compression, the conductive particles are compressed between the semiconductor light emitting device and the wiring electrode to electrically connect the semiconductor light emitting device and the wiring electrode. In order for the semiconductor light emitting device and the wiring electrode to be electrically connected, a predetermined level or higher of pressure should be applied to the conductive particles.

Hereinabove, an example has been described in which the conductive adhesive layer is provided in the form of a film or paste in order to transfer the semiconductor light emitting device of the display device according to an embodiment of the present disclosure and then to electrically connect the semiconductor light emitting device to the wiring electrode. Hereinafter, a display device capable of simplifying a process, reducing cost, and securing mass productivity by providing a patterned adhesive pattern having both transfer property and adhesive property, and a manufacturing method thereof will be described with reference to FIG. 9.

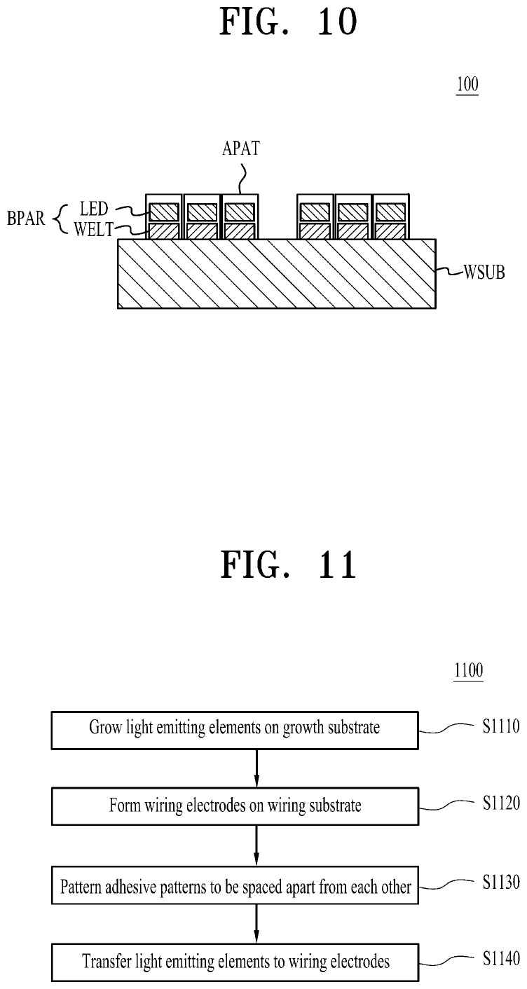

FIGS. 9 and 10 are diagrams each illustrating a display device according to an embodiment of the present disclosure.

Referring to FIGS. 9 and 10, a display device 100 according to an embodiment of the present disclosure includes a wiring substrate WSUB, wiring electrodes WELT, light emitting devices, and adhesive patterns APAT.

The wiring substrate WSUB may be the substrate 110 of FIG. 2 or the substrate 210 of FIG. 6 described above. In other words, the wiring substrate WSUB is a flexible substrate and may be implemented by a material, such as PEN or PET, which is insulative and flexible.

At least some of the wiring electrodes WELT are positioned on the wiring substrate WSUB. FIGS. 9 and 10 show that the wiring electrodes WELT protrude from the surface of the wiring substrate WSUB. For example, the wiring electrodes WELT may be formed by depositing a metal material on the surface of the wiring substrate WSUB and then etching the metal material. Alternatively, the wiring electrodes WELT may be formed by oxidizing a partial area on a separate metal layer and then bonding the metal layer to the wiring substrate WSUB. However, the wiring electrodes WELT are not limitedly formed by the above-mentioned method and may be positioned inwardly from the surface of the wiring substrate WSUB. For example, the wiring electrodes WELT may be formed by etching the surface of the wiring substrate WSUB, filling the etched surface of the wiring substrate WSUB with a metal material, and then sintering the metal material.

Each of the light emitting devices is electrically connected to a corresponding wiring electrode among the wiring electrodes WELT. The light emitting devices may be implemented as light emitting diodes (LEDs). In particular, each of the light emitting devices may be implemented as a rectangular or square micro-LED having a side length of 100 μm or less, 80 μm or less, or 10 μm or less. Although FIGS. 9 and 10 show simplified light emitting devices, the light emitting devices may have identical or similar structures to the semiconductor light emitting devices 150 and 250 described above. For example, the light emitting devices may be provided as the flip-chip type semiconductor light emitting device 150 of FIG. 4 or the vertical semiconductor light emitting device 250 of FIG. 8.

When the light emitting devices are implemented as the structure of the flip-chip type semiconductor light emitting device 150 of FIG. 4, the light emitting devices may include a p-type semiconductor layer, an n-type semiconductor layer, an active layer formed between the p-type semiconductor layer and the n-type semiconductor layer, and a p-type electrode and an n-type electrode formed on the p-type semiconductor layer and the n-type semiconductor layer, respectively, and spaced apart from each other in a horizontal direction. When the light emitting devices are implemented as the structure of the vertical semiconductor light emitting device 250 of FIG. 8, the light emitting devices may include a p-type semiconductor layer, an n-type semiconductor layer, and an active layer formed between the p-type semiconductor layer and the n-type semiconductor layer, and a p-type electrode and an n-type electrode formed on the p-type semiconductor layer and the n-type semiconductor layer, respectively, and formed facing each other with the p-type semiconductor layer, the active layer, and the n-type semiconductor layer interposed therebetween. Hereinafter, the p-type electrode and the n-type electrode of the light emitting device will be described as a first device electrode and a second device electrode, respectively.

The wiring electrodes WELT may include first wiring electrodes and second wiring electrodes electrically connected to corresponding device electrodes, respectively, among first device electrodes and second device electrodes of the light emitting devices.

When the light emitting devices are implemented in a flip-chip form, all of the wiring electrodes WELT may be positioned on the wiring substrate WSUB. That is, both the first wiring electrodes and the second wiring electrodes may be formed on the wiring substrate WSUB. For example, when the light emitting devices have a flip-chip form and the display device 100 is implemented as the structure illustrated in FIG. 3A, the wiring electrodes WELT of FIGS. 9 and 10 may be interpreted as a concept including the first electrode 120, the second electrode 140, and the auxiliary electrode 170 of FIG. 3A. However, the wiring electrodes WELT are not limited to such a structure. Unlike FIG. 3A, the wiring electrodes WELT of FIGS. 9 and 10 may have the first wiring electrodes and the second wiring electrodes with different heights, corresponding to the first electrode 120 and the second electrode 140 of FIG. 3A, respectively, so that the auxiliary electrode 170 of FIG. 3A may not be separately included.

When the light emitting devices are implemented in a vertical form, the first wiring electrodes among the wiring electrodes WELT are formed on the wiring substrate WSUB, and the second wiring electrodes thereamong may be formed facing the first wiring electrodes with the light emitting devices interposed between the first wiring electrodes and the second wiring electrodes. However, the wiring electrodes WELT are not limited to the above structure. For example, when the display device 100 is implemented as the structure illustrated in FIG. 6 even though the light emitting devices are in a vertical form, that is, when the second electrode 240 is formed on top of the n-type electrode so that the second electrode 240 is not directly connected to the n-type electrode but the second electrode 240 is connected to the n-type electrode by a connecting electrode protruding from the second electrode 240, both the first wiring electrodes and the second wiring electrodes of the wiring electrodes WELT may be formed on the wiring substrate WSUB. In this case, the wiring electrodes WELT of FIGS. 9 and 10 may be interpreted as a concept including the first electrode 220, the second electrode 240, and the connecting electrode of FIG. 6.

Referring continuously to FIGS. 9 and 10, a pixel PX, which is a minimum unit constituting an image, may include three unit pixels, i.e., three light emitting devices. However, the display device 100 may set the number of light emitting devices included in each pixel PX differently from the above configuration if necessary. The light emitting devices may implement corresponding colors, respectively. For example, the light emitting devices may represent three primary colors of light, i.e., red (R), green (G), and blue (B), respectively. The display device 100 may adopt various structures so that the light emitting devices implement corresponding colors.

FIG. 9 illustrates an example in which three light emitting devices constituting one pixel PX are all provided as LEDs of the same color (e.g., blue LEDs). In this case, other colors (e.g., red and green) may be implemented through a phosphor layer (e.g., the phosphor conversion layer 180 of FIG. 3B) positioned on the outer surfaces of the blue light emitting devices.

Unlike this case, FIG. 10 illustrates an example in which three light emitting devices constituting one pixel PX implement R. G, and B by themselves, respectively. For example, the light emitting devices of FIG. 10 may implement R, G. and B by themselves by adding In and/or Al to GaN. Alternatively, the light emitting devices of FIG. 10 may implement R, G, and B by themselves by adjusting the particle size of QDs.

Unlike FIG. 9 or 10, two of the three light emitting devices constituting one pixel may be implemented as blue LEDs and the remaining one may be implemented as a green LED, so that a red phosphor may be added to one of the two blue LEDs. In addition, the display device 100 may implement the pixel with the structure illustrated in FIG. 5B or 5C.

The light emitting devices emit light as electricity is applied through the wiring electrodes WELT. Hereinafter, a pair consisting of a wiring electrode and a light emitting element that are electrically connected to each other among the light emitting devices and the light emitting devices (the wiring electrodes WELT) is referred to as a bonding pair BPAR. The adhesive patterns APAT adhere the wiring electrodes WELT and the light emitting devices, respectively. In this case, each of the adhesive patterns APAT includes at least one bonding pair BPAR and the adhesive patterns APAT are spaced apart from each other.

The adhesive patterns APAT may include the same number of bonding pairs BPAR, respectively. For example, as illustrated in FIG. 9, each of the adhesive patterns APAT1 and APAT2 may include three bonding pairs BPAR, or as illustrated in FIG. 10, each of the adhesive patterns APAT may include one bonding pair BPAR.

The adhesive patterns APAT according to an embodiment of the present disclosure have both adhesive property and transfer property. That is, the adhesive patterns APAT according to an embodiment of the present disclosure have adhesive property that allow the light emitting devices and the wiring electrodes WELT to adhere to each other, and transfer property that prevent the light emitting devices from being damaged due to impact caused by laser when a damaged light emitting device is transferred to the wiring electrode WELT.

The adhesive patterns APAT according to an embodiment of the present disclosure may be formed of a non-conductive paste (NCP). The NCP according to an embodiment of the present disclosure includes a thermosetting composition and a UV B-stage composition together. For example, the NCP according to an embodiment of the present disclosure may include a thermosetting composition, such as a thermosetting reactive resin, a thermosetting curing agent, a thermosetting catalyst, and an epoxy and include a UV B-stage composition (a UV reactive resin or a UV initiator), such as acrylate and epoxy acrylate.

When the light emitting device is transferred to the wiring electrode (WELT), the light emitting device and the wiring electrode WELT are temporarily bonded in a semi-solid state by the UV B-stage composition. Therefore, even if a growth substrate GSUB is removed through laser lift-off (LLO), the adhesive patterns APAT according to an embodiment of the present disclosure may prevent the light emitting device from being damaged by improving impact resistance of the light emitting device.

That is, the display device 100 according to an embodiment of the present disclosure does not cause a problem such as damage of the light emitting device even if the light emitting device is directly transferred from the growth substrate GSUB to the wiring substrate WSUB, without the necessity of using a flexible temporary substrate such as polydimethylsiloxane (PDMS).

Here, when the light emitting device is transferred to the wiring electrode WELT through a semi-curing process for the adhesive pattern APAT according to an embodiment of the present disclosure, the light emitting device and the wiring electrode WELT may be in a semi-solid state. For example, the semi-curing process may be a UV B-stage process.

In addition, the content of the UV B-stage composition in the total NCP may be determined based on the relationship between action of preventing the light emitting device from being damaged by absorbing impact caused by laser used when the light emitting device is separated from the growth substrate GSUB and action of securing the adhesive strength and conductivity of the adhesive pattern APAT in a bonding process. That is, the content of the UV B-stage composition in the total NCP may vary depending on the degree of a semi-solid state (the degree of fluidity) of the adhesive pattern APAT required. For example, if the content of the UV B-stage composition is insufficient, the fluidity of the adhesive pattern APAT is excessive and thus impact caused by laser is not sufficiently absorbed. If the content of the UV B-stage composition is excessive, the fluidity of the adhesive pattern APAT is insufficient, resulting in a lack of adhesive strength and poor pressing of conductive balls during the bonding process.

For example, the content of the UV B-stage composition according to an embodiment of the present disclosure may constitute 20 to 50% of the content of the total NCP. As confirmed in the following table, when the content of the UV B-stage composition is less than 20% or greater than 50%, damage may occur by laser, or defects may occur in pressing of conductive balls or in adhesion.

TABLE 1

| | Em- | Em- | Em- | Com- | Com- | Com- |
|---|---|---|---|---|---|---|
| | bodi- | bodi- | bodi- | parative | parative | parative |
| | ment | ment | ment | Example | Example | Example |
| | 1 | 2 | 3 | 1 | 2 | 2 |
| Content (%) | 20 | 35 | 50 | 0 | 10 | 65 |
| of UV | | | | | | |
| composition | | | | | | |
| Content(%) | 80 | 65 | 50 | 100 | 90 | 35 |
| of | | | | | | |
| thermosetting | | | | | | |
| composition | | | | | | |
| Damage | Un- | Un- | Un- | Damaged | Damaged | Un- |
| property | dam- | dam- | dam- | | | dam- |
| caused by | aged | aged | aged | | | aged |
| laser | | | | | | |
| Pressing of | Good | Good | Good | Good | Good | Poor |
| conductive | | | | | | |
| balls | | | | | | |
| Adhesion | Good | Good | Good | Good | Good | Poor |

In this case, the NCP forming the adhesive patterns APAT according to an embodiment of the present disclosure may have a viscosity of 10,000 to 100,000 centipoise (cps) in order to perform printing for patterning and secure molding property for the bonding pair BPAR after patterning.

As such, the adhesive patterns APAT according to an embodiment of the present disclosure are phase-changed from the NCP of a liquid state to a semi-solid state through a semi-curing process in a transfer procedure. Therefore, even if the NCP is used alone, the adhesive patterns APAT have both adhesive property and transfer property.

Therefore, since a process of transferring the light emitting device from the growth substrate GSUB onto a temporary substrate such as PDMS is omitted, the display device 100 according to an embodiment of the present disclosure prevents the problem of positional movement of the light emitting device due to a decrease in the number of times of transfer, so that positioning accuracy on the growth substrate GSUB may be applied and process simplification, cost reduction, and mass productivity securement may be achieved.

As described above, the adhesive patterns APAT according to an embodiment of the present disclosure may be formed using only the NCP alone as opposed to the anisotropic conductive layer used in the display device 100 of FIG. 2. In this case, before the adhesive patterns APAT according to an embodiment of the present disclosure are patterned with respect to the light emitting device or the wiring electrode WELT, conductive particles such as conductive balls may be located on the growth substrate GSUB or the wiring substrate WSUB. However, the adhesive patterns APAT are not limited to the above configuration, and the adhesive patterns (APAT) according to an embodiment of the present disclosure may be formed of a conductive paste including conductive balls.

Hereinafter, a manufacturing method applicable to the display device 100 according to an embodiment of the present disclosure will be described.

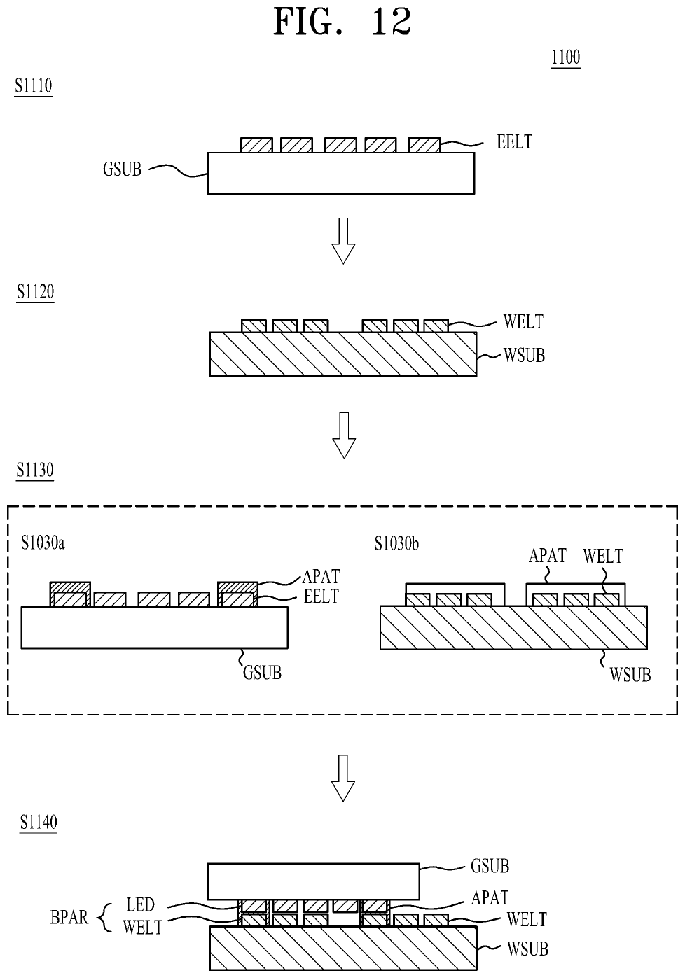

FIG. 11 is a flowchart illustrating a manufacturing method of a display device according to an embodiment of the present disclosure, and FIG. 12 is a diagram illustrating an embodiment of the manufacturing method of FIG. 11.

Referring to FIGS. 11 and 12, a method 1100 of manufacturing a display device according to an embodiment of the present disclosure includes growing light emitting devices on a growth substrate GSUB (S1100), forming at least a part of wiring electrodes WELT on a wiring substrate WSUB (S1120), patterning adhesive patterns APAT spaced apart from each other and having adhesive property for bonding the light emitting devices and the wiring electrodes WELT and transfer property required to transfer the light emitting devices to the wiring electrode WELT and (S1130), and transferring the light emitting devices to the wiring electrodes WELT so that bonding pairs BPAR each consisting of a corresponding wiring electrode and a corresponding light emitting device among the wiring electrodes WELT and the light emitting devices are bonded through the adhesive patterns APAR (S1140).

The operation (S1100) of growing the light emitting devices on the growth substrate GSUB may implement the light emitting devices of a chip type by growing an epitaxial material on the growth substrate GSUB of a sapphire or silicon material. For example, in the case of the growth substrate (GSUB) of the sapphire material, the light emitting devices of GaN may be grown through a runtime of 6 to 8 hours using various sources at a high temperature of 550° C. or higher. When the light emitting devices are formed in a wafer unit, the light emitting devices may be matched to correspond to spacings and sizes used in the display device 100, that is, the spacings or positions of the wiring electrode WELT, so that manufacturing convenience of the display device 100 may be increased. The grown light emitting devices may be the flip-chip micro-LEDs or vertical micro-LEDs described above.

While the operation (S1120) of forming the wiring electrodes WELT on the wiring substrate WSUB may be performed through the process of depositing a metal material on the surface of the wiring substrate WSUB and etching the metal material as described above, the operation of forming the wiring electrode WELT is not limited to the above configuration. In order for the display device 100 to be implemented flexibly, the wiring substrate WSUB may include polyimide (PI). When the display device 100 has the structure of FIG. 2, first wiring electrodes and second wiring electrodes among the wiring electrodes WELT may be disposed in a direction orthogonal to each other.

The adhesive patterns APAT may be patterned on the growth substrate GSUB or on the wiring substrate WSUB. When the adhesive patterns APAT are formed on the growth substrate GSUB (S1130a), each of the adhesive patterns APAT may include at least one light emitting device. When the adhesive patterns APAT are formed on the wiring substrate WSUB (S1130b), each of the adhesive patterns APAT may include at least one wiring electrode WELT.

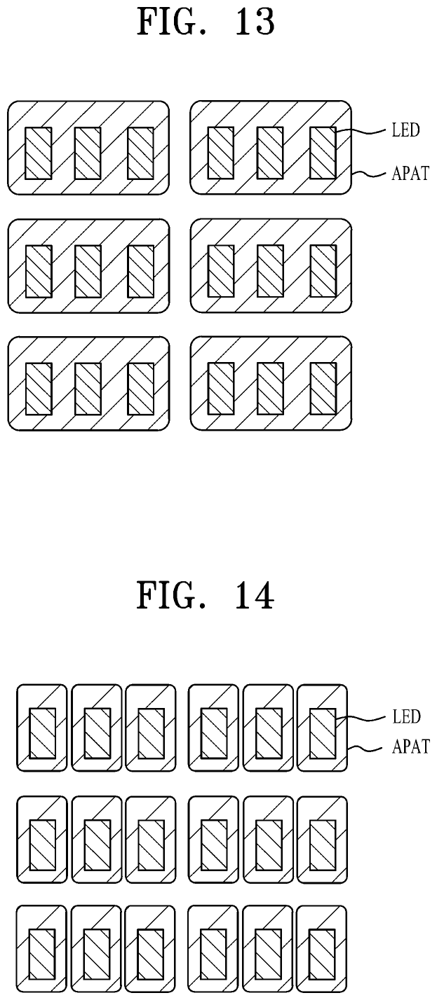

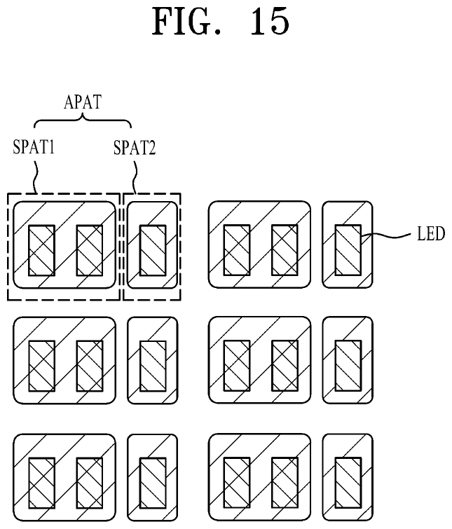

As described above, the adhesive patterns APAT may be patterned to correspond respectively to the same number of bonding pairs BPAR among the bonding pairs BPAR For example, referring to FIGS. 13 and 14 each illustrating an adhesive pattern APAT according to an embodiment of the present disclosure, all of the adhesive patterns APAT may be patterned to include three light emitting devices or patterned to include one light emitting device.

However, the adhesive patterns APAT are not limited to the above configuration. Some of the adhesive patterns APAT may be patterned to correspond to a different number of bonding pairs BPAR from other adhesive patterns. For example, referring to FIG. 15 illustrating adhesive patterns APAT according to an embodiment of the present disclosure, each of first sub-patterns SPAT1 among the adhesive patterns APAT may be patterned to include two light emitting devices, whereas each of second sub-patterns SPAT2 may be patterned to include two light emitting devices (one light emitting device). While FIG. 15 illustrates that two adjacent light emitting devices form the first sub-pattern SPAT1, the first sub-patterns SPAT1 are not limited to the above configuration. For example, each of the first sub-patterns SPAT1 may be patterned to include two light emitting devices spaced apart from each other.

As illustrated in FIGS. 13 to 15, each of the adhesive patterns APAT may be patterned so as to mold, i.e., integrally surround, the light emitting devices included therein and to be spaced apart from other adhesive patterns. When the adhesive patterns APAT are patterned with respect to the light emitting devices, an amount of the NCP in which one or more bonding pairs BPAR included in one adhesive pattern APAR are capable of being molded will be used for each adhesive pattern APAT so that even the wiring electrode WELT forming the bonding pair BPAR through a later transfer process may be molded.

The adhesive patterns APAT may be patterned in various forms without being limited to embodiments of FIGS. 13 to 15. For example, each of the adhesive patterns APAT may have a different number of bonding pairs BPAR in correspondence to a color implementation structure of the light emitting devices. As described above, three light emitting devices constituting one pixel may include the same blue LEDs or may implement R, G, and B, respectively, by themselves. In the former case, the adhesive patterns APAT may be implemented according to the embodiment of FIG. 13, and in the latter case, the adhesive patterns APAT may be implemented according to the embodiment of FIG. 14. As such, since light emitting devices transferred and light emitting devices not transferred at any time are included in different adhesive patterns, conditions required to separate the light emitting devices from the growth substrate (GSUB in FIG. 12) during transfer are alleviated, so that impact applied to the light emitting devices may be further alleviated.

While FIGS. 13 to 15 illustrate an example in which the adhesive patterns APAT are formed on the growth substrate GSUB, the adhesive patterns APAT are not limited to the above configuration. As illustrated in S1130b of FIG. 12, the adhesive patterns APAT may be formed on the wiring substrate WSUB, and in this case, may be formed with respect to the wiring electrodes WELT in the same manner as in FIGS. 13 to 15. In addition, similarly to formation of the adhesive patterns APAT for the light emitting devices, each of the adhesive patterns APAT may be patterned to integrally surround a wiring electrode WELT or wiring electrodes WELTs included therein and to be spaced apart from other adhesive patterns. When the adhesive patterns APAT are formed on the wiring substrate WSUB, the adhesive patterns APAT may be implemented as the embodiment of FIG. 15 with respect to the embodiment in which two of the three light emitting devices constituting one pixel are implemented as blue LEDs and one is implemented as a green LED. The amount of the NCP used for each adhesive pattern APAT is the same as in the case in which the above-described adhesive pattern APAT is formed on the growth substrate GSUB.

Referring back to FIGS. 11 and 12, the operation (S1130) of patterning the adhesive patterns APAT may be performed by dispensing, pattern-printing, or inkjet-printing an adhesive material. The NCP may be used as the adhesive material. A specific configuration and property of the NCP forming the adhesive patterns APAT are as described above.

Prior to performing the operation (S1130) of patterning the adhesive patterns APAT, an operation of placing conductive particles on the wiring substrate WSUB or the growth substrate GSUB may be further included.

After the adhesive patterns APAT are patterned on the growth substrate GSUB (S1130a) or patterned on the wiring substrate WSUB (S1130b), the light emitting devices are transferred to the wiring electrodes WELT (S1140). Bonding pairs BPAR of the light emitting devices and the wiring electrodes WELT may be formed only by a single transfer operation through the islanded adhesive patterns APAT having both adhesive property and transfer property.

At the same time as the transfer operation or immediately after performing the transfer operation, a semi-curing process may be performed on the adhesive patterns APAT of a liquid NCP type to change a phase to a semi-solid state. For example, the semi-curing process may be a UV B-stage. Through the UV semi-curing process, a UV B-stage composition among materials constituting the NCP reacts, so that the adhesive patterns APAT have a semi-solid state, and a corresponding light emitting device and a corresponding wiring electrode WELT of the bonding pair BPAR are temporarily bonded.

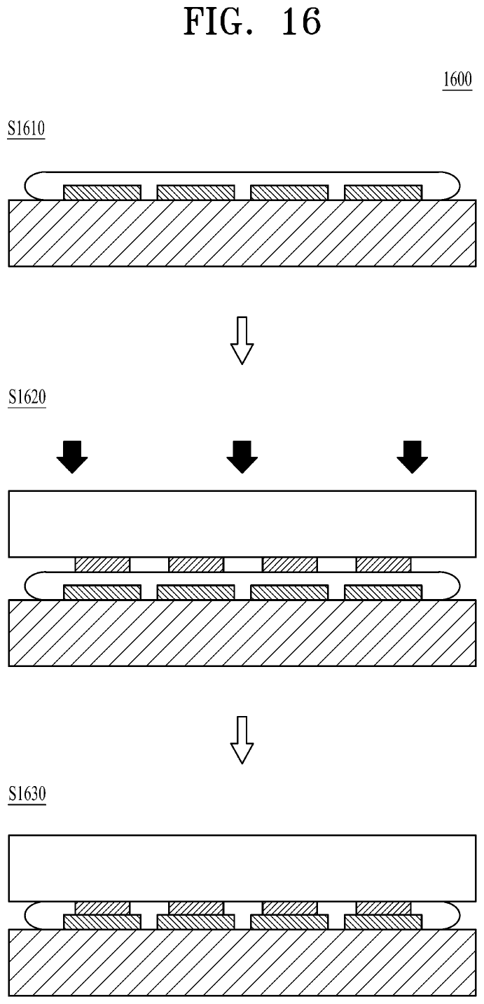

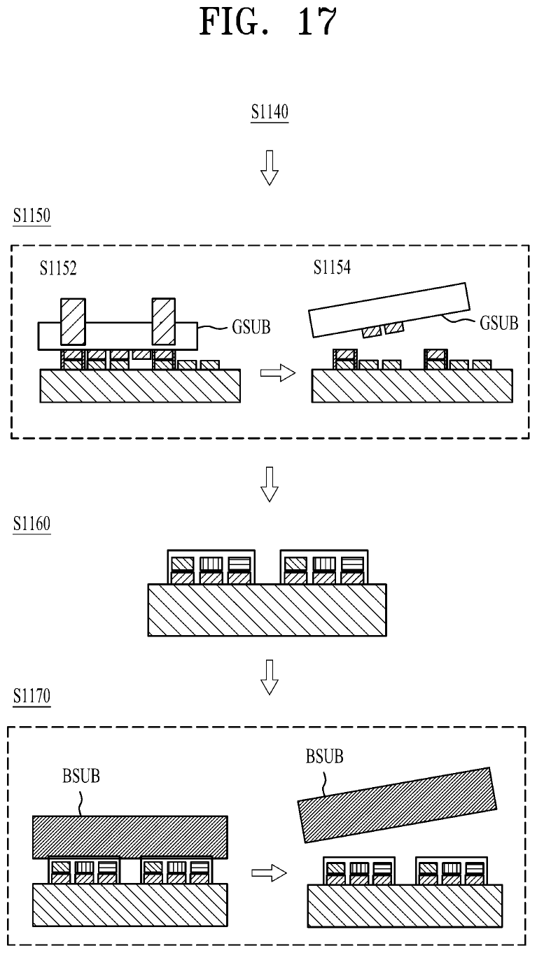

FIG. 16 is a diagram illustrating a manufacturing method of a display device according to a comparative example compared with the present disclosure.

Referring to FIG. 16, when a method 1600 of manufacturing the display device according to the comparative example includes coating an NCP (S1610), bonding light emitting devices and wiring electrodes through thermal compression (S1620), and performing thermal curing (S1630), using the NCP that does not contain a UV B-stage composition or without proceeding a UV semi-curing process in order to express adhesive property, damage to the light emitting devices may be problematic in removing a growth substrate through LLO.

On the other hand, according to the manufacturing method of the display device according to the embodiment of the present disclosure, a corresponding light emitting device and wiring electrode WELT of a bonding pair BPAR may be temporarily bonded in a semi-cured state, resulting in preventing the light emitting device from being damaged.

FIG. 17 is a diagram illustrating a manufacturing method of a display device according to an embodiment of the present disclosure.

Referring to FIGS. 12 and 17, the method 1100 of manufacturing the display device according to an embodiment of the present disclosure may further include performing LLO on the growth substrate GSUB (S1150) after transferring the light emitting devices to the wiring electrodes WELT (S1140). That is, the growth substrate GSUB is irradiated with laser (shaped as two bars inserted into the growth substrate GSUB) (S1152), and the growth substrate GSUB is separated (S1154). Therethrough, the light emitting devices are separated from the growth substrate GSUB and transferred to the wiring electrodes WELT.

In this way, since the adhesive patterns APAT are provided in a semi-solid state when the light emitting devices are separated from the growth substrate GSUB, impact applied to the light emitting devices by laser may be alleviated. In addition, since a sufficient flow space of an adhesive material is secured due to a separated space between islanded (molded) adhesive patterns APAT, gap filling property or bonding property may be maintained. Therefore, yield and performance may be improved even for a large-area process.

As in the example of the LLO operation (S1150) of FIG. 17, when a light emitting device, which is a unit pixel constituting each pixel, exhibits a different color, only one light emitting device among pixels will be separated from the growth substrate GSUB through a single LLO process. However, when all light emitting devices, each of which is a unit pixel constituting each pixel, include LEDs of the same color (e.g., blue LEDs), all light emitting devices constituting each pixel will be separated from the growth substrate GSUB through the single LLO process.

When a light emitting device constituting each pixel exhibits a different color, the operation (S1150) of transferring the light emitting devices to the wiring electrodes WELT may be repeated a number of times corresponding to colors implemented by the light emitting devices to complete transfer for each pixel (S1160).

After the transfer operation for each pixel is completed (S1160), the bonding pairs BPAR are thermally compressed and bonded (S1170). In this case, this process is performed in a state in which a bonding substrate BSUB temporarily provided to protect bonding pairs BPAR during the thermal compression bonding process is mounted, and the bonding substrate BSUB is removed after the thermal compression bonding process is ended.

As such, according to the method 1100 for manufacturing the display device according to an embodiment of the present disclosure, light emitting devices exhibiting different colors are individually transferred and then bonded simultaneously, thereby preventing lighting failure caused by interference and collision that may occur during sequential bonding.

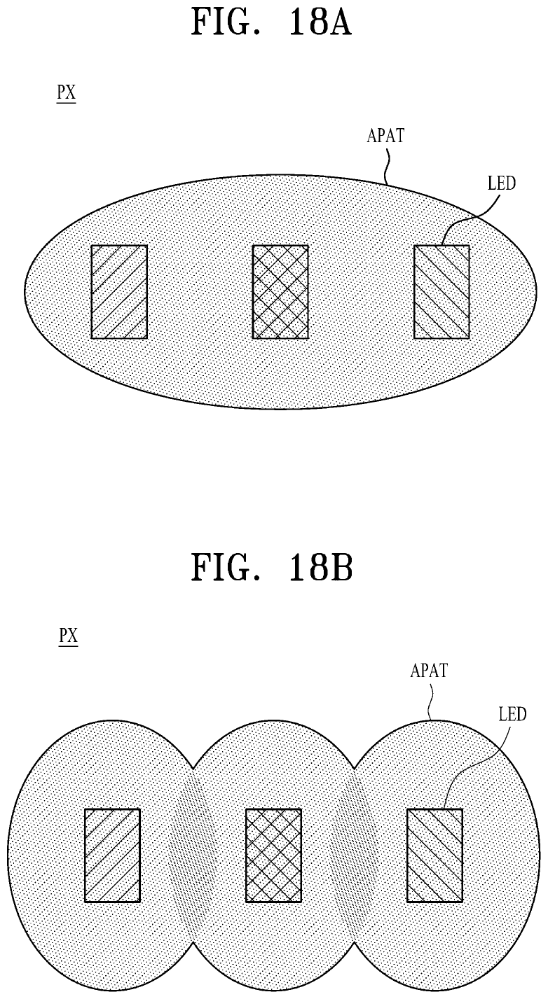

FIG. 18A is a diagram conceptually illustrating the shape of an adhesive pattern after completion of a bonding operation according to an embodiment of the present disclosure, and FIG. 18B is a diagram conceptually illustrating the shape of an adhesive pattern after completion of a bonding operation according to a comparative example compared with the present disclosure.

As illustrated in FIG. 18A, the method 1100 of manufacturing the display device according to an embodiment of the present disclosure includes transferring each pixel PX (S1160) and then thermally compressing and bonding the bonding pairs BPAR (S1170) as illustrated in FIG. 17, so that an adhesive pattern APAT for the pixel PX may be formed in a shape having a constant curvature. In contrast, as illustrated in FIG. 18B, when a bonding operation should be individually performed for each light emitting device of each pixel PX because there is no semi-curing process, the adhesive pattern APAT for the pixel PX has a curvature varying with a position. In FIGS. 18A and 18B, while the adhesive pattern APAT after bonding is illustrated in an elliptical shape, the adhesive pattern APAT is not limited to such a shape. For example, the adhesive pattern APAT after bonding may be implemented in a rectangular shape.

Referring back to FIGS. 11 and 12, an example of the transfer operation (S1140) is illustrated in which a light emitting device exhibiting one of R, G, and B constituting each pixel is transferred to form a bonding pair BPAR together with a corresponding wiring electrode WELT. However, the transfer operation is not limited to the above configuration. In the case in which the light emitting devices constituting one pixel include LEDs of the same color (e.g., blue LEDs), the operation of transferring the light emitting devices to the wiring electrodes WELT (S1140) may form bonding pairs BPAR together with corresponding wiring electrodes WELT by transferring the light emitting devices constituting each pixel altogether.

The display device using the semiconductor light emitting devices described above is not limited to the configurations and methods of the above-described embodiments. Rather, all or a part of the embodiments may be selectively combined and configured so that various modifications may be made.

1. A display device, comprising:
a wiring substrate;
wiring electrodes, at least a part of which is disposed on the wiring substrate;
light emitting devices connected electrically to related wiring electrodes, respectively, among the wiring electrodes; and
adhesive patterns having adhesive property for bonding the wiring electrodes and the light emitting devices and transfer property required to transfer the light emitting devices to the wiring electrode,
wherein the adhesive patterns are formed respectively for at least one bonding pair including a wiring electrode and a light emitting device connected electrically among the wiring electrodes and the light emitting devices and are spaced apart.

2. The display device of claim 1, wherein the adhesive patterns are respectively related to an identical number of bonding pairs among the bonding pairs.

3. The display device of claim 1, wherein first sub-patterns among the adhesive patterns are respectively related to a first number of bonding pairs among the bonding pairs, and second sub-patterns among the adhesive patterns are respectively related to a second number of bonding pairs among the bonding pairs.

4. The display device of claim 1, wherein each of the adhesive patterns is formed to integrally surround bonding pairs included in the adhesive pattern.

5. The display device of claim 1, wherein each of the adhesive patterns is formed of a non-conductive paste (NCP) phase-changeable to a semi-solid state.

6. The display device of claim 5, wherein the NCP includes an ultraviolet (UV) B-stage composition and a thermosetting composition.

7. The display device of claim 6, wherein content of the UV B-stage composition in the NCP is 20% to 50%.

8. The display device of claim 6, wherein the NCP has a viscosity of 10,000 to 100,000 centipoise (cps).

9. The display device of claim 5, wherein the NCP includes at least one of acrylate or epoxy acrylate.

10. The display device of claim 1, wherein an adhesive pattern related to bonding pairs constituting one pixel among the at least one bonding pair has a constant curvature.

11. The display device of claim 1,
wherein the wiring electrodes include first wiring electrodes and second wiring electrodes electrically connected to related device electrodes, respectively, among first device electrodes and second device electrodes of the light emitting devices; and
wherein all of the first wiring electrodes and the second wiring electrodes are formed on one surface of the wiring substrate.

12. The display device of claim 1,
wherein the wiring electrodes include first wiring electrodes and second wiring electrodes electrically connected to related device electrodes, respectively, among first device electrodes and second device electrodes of the light emitting devices, and
wherein the first wiring electrodes are formed on one surface of the wiring substrate and the second wiring electrodes are formed facing the first wiring electrodes with the light emitting devices interposed between the first wiring electrodes and the second wiring electrodes.

13. The display device of claim 1, wherein each of the light emitting devices includes a micro-light emitting device (LED).

14. A method of manufacturing a display device, the method comprising:
growing light emitting devices on a growth substrate;
forming at least a part of wiring electrodes on a wiring substrate;
patterning adhesive patterns spaced apart from each other and having adhesive property for bonding the wiring electrodes and the light emitting devices and transfer property required to transfer the light emitting devices to the wiring electrode; and
transferring the light emitting devices to the wiring electrodes so that bonding pairs each including a related wiring electrode and a related light emitting device among the wiring electrodes and the light emitting devices are bonded through the adhesive patterns.

15. The method of claim 14, wherein the pattering the adhesive patterns includes performing patterning by dispensing, pattern-printing, or inkjet-printing an adhesive material on the wiring substrate.

16. The method of claim 14,
wherein the patterning the adhesive patterns includes at least one of:
patterning the adhesive patterns to be related respectively to the same number of bonding pairs among the bonding pairs; or
patterning first sub-patterns among the adhesive patterns to be related respectively to a first number of bonding pairs among the bonding pairs, and patterning second sub-patterns among the adhesive patterns to be related respectively to a second number of bonding pairs among the bonding pairs.

17. The method of claim 14, further comprising phase-changing the adhesive patterns to a semi-solid state at the same time as the transferring the light emitting devices to the wiring electrodes or immediately after the transferring the light emitting devices to the wiring electrodes.

18. The method of claim 17, wherein the phase-changing the adhesive patterns to the semi-solid state includes an ultraviolet (UV) B-stage.

19. The method of claim 17, further comprising performing laser lift-off (LLO) on the growth substrate after the phase-changing the adhesive patterns to the semi-solid state.

20. The method of claim 14, further comprising:
repeating the transferring the light emitting devices to the wiring electrodes to complete transfer for each pixel; and
simultaneously thermally compressing and bonding light emitting devices of each pixel after completing the transferring each pixel.
